(19) United States
(12) Patent Application Publication
(10) Pub. No.: US 2012/0014191 A1
(43) Pub. Date: Jan. 19, 2012

(54) SEMICONDUCTOR MEMORY DEVICE

(75) Inventors: Azuma SUZUKI, Tokyo (JP); Fumihiko TACHIBANA, Tokyo (JP); Tomoaki YABE, Tokyo (JP)

(73) Assignee: KABUSHIKI KAISHA TOSHIBA, Tokyo (JP)

(21) Appl. No.: 13/181,404

(22) Filed: Jul. 12, 2011

(30) Foreign Application Priority Data
Jul. 13, 2010 (JP) P2010-158700

(51) Int. Cl. G11C 7/00

(52) U.S. Cl. 365/189.07; 365/189.011

(57) ABSTRACT

A semiconductor memory device of an embodiment includes memory cells 2, a write-back determining unit 7, and a read controller 8. Each memory cell 2 is capable of writing and reading through different paths. The write-back determining unit 7 determines whether or not to perform the write-back for a non-selected column, at the time of the write for a selected column. On the basis of the determination result of the write-back determining unit 7, the read controller 8 controls the read of the data used in the write-back for the non-selected column.

### CROSS REFERENCE TO RELATED APPLICATIONS

This application is based upon and claims the benefit of priority from the prior Japanese Patent Application No. 2010-158700, filed on Jul. 13, 2010, the entire contents of which are incorporated herein by reference.

### FIELD

Embodiments of the invention relate to a semiconductor memory device.

### BACKGROUND

As a method for avoiding read disturb, some SRAMs employs 8-transistor cells each of which includes a 6-transistor cell with addition of two transistors dedicated to reading. In addition, write-back is sometimes performed on the 8-transistor cell as a method for addressing write disturb. The write-back method, however, increases the charge/discharge current in the data line and the signal line, and thus increases the power consumption.

### BRIEF DESCRIPTION OF THE DRAWINGS

FIG. 1 is a block diagram illustrating the general configuration of a surrounding area of a memory cell of a semiconductor memory device according to a first embodiment of the invention.

FIG. 2 is a circuit diagram illustrating the general configuration of the memory cell shown in FIG. 1.

FIG. 3A is a timing chart illustrating the waveforms of several portions of the semiconductor memory device shown in FIG. 1 while the semiconductor memory device performs write-back.

FIG. 3B is a timing chart illustrating the waveforms of the portions of the semiconductor memory device shown in FIG. 1 while the semiconductor memory device does not perform write-back.

FIG. 4 is a circuit diagram illustrating the general configuration of a write-back controller shown in FIG. 1.

FIG. 5 is a block diagram illustrating an example of the general configuration of a write-back determining unit employed in the semiconductor memory device shown in FIG. 1.

FIG. 6 is a circuit diagram illustrating an example of a trimming circuit that generates a reference voltage Vref shown in FIG. 5.

FIG. 7 is a block diagram illustrating the general configuration of a surrounding area of a memory cell of a semiconductor memory device according to a second embodiment of the invention.

### DETAILED DESCRIPTION

Semiconductor memory devices of some embodiments of the invention will be described below by referring to the drawings.

### First Embodiment

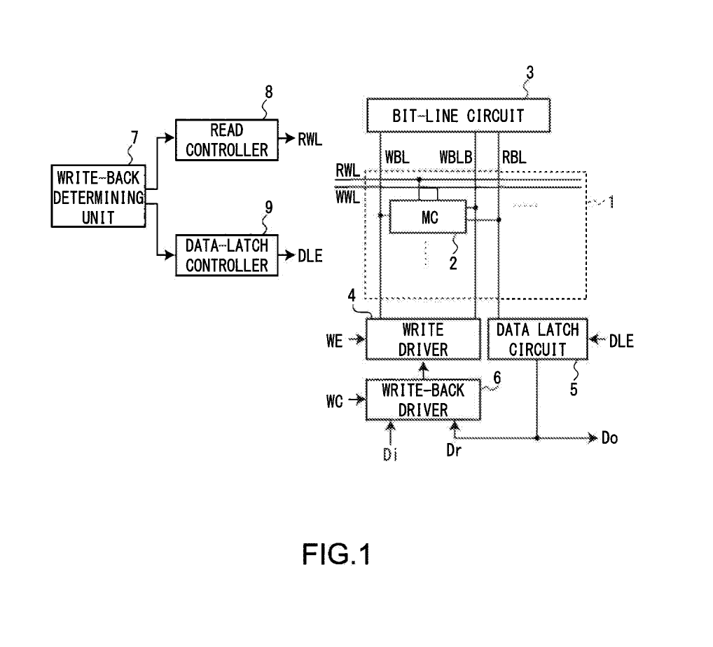

FIG. 1 is a block diagram illustrating the general configuration of a surrounding area of a memory cell of a semiconductor memory device according to a first embodiment of the invention.

The semiconductor memory device shown in FIG. 1 includes a memory-cell array 1, a bit-line load circuit 3, a write driver 4, a data latch circuit 5, a write-back controller 6, a write-back determining unit 7, a read controller 8, and a data-latch controller 9. Note that the bit-line load circuit 3, the write driver 4, the data-latch circuit 5, and the write-back controller 6 may be provided in such a way that each column is provided with one bit-line load circuit 3, one write driver 4, one data-latch circuit 5, and one write-back controller 6.

In the memory-cell array 1, plural memory cells 2 are arranged in a matrix shape, that is, memory cells are arranged both in the row direction and in the column direction. The memory cells 2 can complimentarily store data, so that the memory cells 2 may form, for instance, an SRAM. As each of the memory cells 2, an 8-transistor cell, which is formed by adding two more transistors dedicated to reading to a 6-transistor cell, may be used.

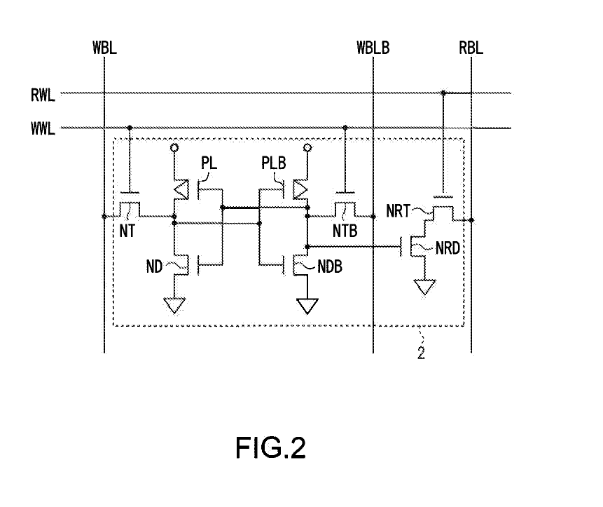

FIG. 2 is a circuit diagram illustrating the general configuration of the memory cell shown in FIG. 1.

The memory cell 2 shown in FIG. 2 includes a pair of drive transistors ND and NDB, a pair of load transistors PL and PLB, a pair of transfer transistors NT and NTB, a transfer transistor NRT dedicated to reading (hereinafter, read-only transfer transistor NRT), and a drive transistor NRD dedicated to reading (hereinafter, read-only driver transistor NRD). Note that P-channel field effect transistors may be used as the load transistors PL and PLB whereas N-channel field effect transistors may be used as the drive transistors ND and NDB, the transfer transistors NT and NTB, the read-only transfer transistor NRT, and the read-only driver transistor NRD.

In addition, the memory cell 2 is provided with a write word line WWL, a read word line RWL, a pair of write bit lines WBL and WBLB, and a read bit line RBL. Note that the write bit lines WBL and WBLB and the read bit line RBL may be arranged in parallel to one another. The write word line WWL and the read word line RWL may be arranged to be normal to the write bit lines WBL and WBLB and the read bit line RBL.

The drive transistor ND and the load transistor PL are connected in series to each other, and thus form a CMOS inverter. The drive transistor NDB and the load transistor PLB are connected in series to each other, and thus form a CMOS inverter. The outputs and the inputs of the pair of CMOS inverters are cross-coupled to one another, and thus a flip-flop is formed.

The drain of the transfer transistor NT is connected to the gate of the drive transistor NDB, the gate of the load transistor PLB, the drain of the drive transistor ND, and the drain of the load transistor PL.

The drain of the transfer transistor NTB is connected to the drain of the drive transistor NDB, the drain of the load transistor PLB, the gate of the drive transistor ND, and the gate of the load transistor PL.

The gate of the read-only driver transistor NRD is connected to the drain of the load transistor PLB whereas the drain of the read-only driver transistor NRD is connected to the drain of the read-only transfer transistor NRT.

The gates of the transfer transistors NT and NTB are connected to the write word line WWL. The gate of the read-only transfer transistor NRT is connected to the read word line RWL. The source of the transfer transistor NT is connected to the write bit line WBL. The source of the transfer transistor NTB is connected to the write bit line WBLB. The source of the read-only transfer transistor NRT is connected to the read bit line RBL.

The bit-line load circuit 3 shown in FIG. 1 is capable of applying load to the write bit lines WBL and WBLB as well as to the read bit line RBL. For instance, the bit-line load circuit 3 can set the potentials of the write bit lines WBL and WBLB and of the read bit line RBL at the high level at the time of resetting.

The write driver 4 is capable of driving the write bit lines WBL and WBLB on the basis of write data Di or write-back data Dr selected by the write-back controller 6.

The data latch circuit 5 is capable of latching data read from the memory cells 2 through the read bit line RBL, and of outputting the data as read data Do or write-back data Dr. Note that a sense amplifier, for instance, may be used as the data latch circuit 5.

The write-back controller 6 is capable of selecting either the write data Di or the write-back data Dr on the basis of a write select signal WC, and of outputting the selected data to the write driver 4.

The write-back determining unit 7 is capable of determining whether or not to perform the write-back for non-selected columns, at the time of the write for the selected column.

The read controller 8 is capable of controlling the read of data used in the write-back for the non-selected columns on the basis of the determination result of the write-back determining unit 7.

The data-latch controller 9 allows the data read from the non-selected columns to be latched on the basis of the determination result of the write-back determining unit 7.

In the memory cell 2 shown in FIG. 2, when the read data Do is read from the selected cell, the write word line WWL is at the low level and the read word line RWL is at the high level. As a consequence, the read-only transfer transistor NRT is turned on with the transfer transistors NT and NTB in the off state, so that the data stored in the selected cell is read through the read bit line RBL. Accordingly, when data is read from the selected cell, the transfer transistors NT and NTB of the memory cells 2 in the non-selected columns are kept in the off state. Consequently, disturb fault can be prevented.

In the memory cell 2 shown in FIG. 2, when the write data Di is written into the selected cell, the write word line WWL is at the high level. As a consequence, the transfer transistors NT and NTB are turned on, so that the write data Di is supplied to the selected cell through the write bit lines WBL and WBLB. In the meanwhile, the transfer transistors NT and NTB in each memory cell 2 in each non-selected column are also turned on. Accordingly, if the operation margins of the memory cells 2 become smaller along with the miniaturization of the memory cells 2, disturb fault occurs.

Thus, the write-back determining unit 7 is capable of determining, on the basis of the operation margins of the memory cells 2, whether or not to perform the write-back for each memory cell 2 in each non-selected column. The write-back is performed if the operation margins of the memory cells 2 are not enough to prevent disturb fault. In contrast, the write-back is not performed if the operation margins of the memory cells 2 are enough to prevent disturb fault.

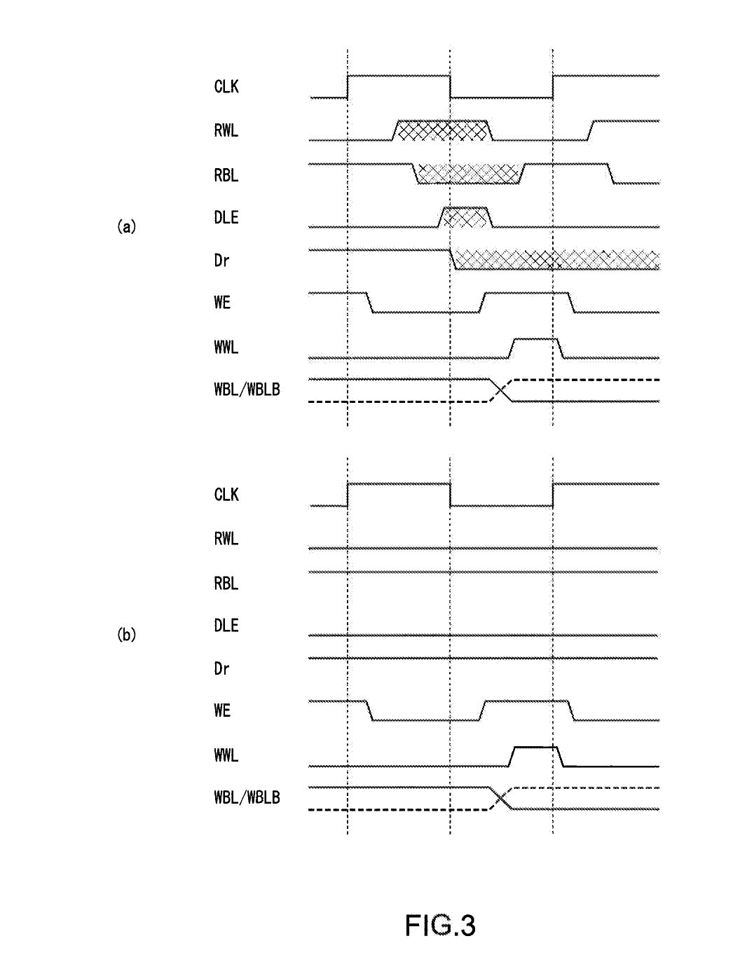

FIG. 3A is a timing chart illustrating the waveforms of several portions of the semiconductor memory device shown in FIG. 1 while the semiconductor memory device performs write-back. FIG. 3B is a timing chart illustrating the waveforms of the portions of the semiconductor memory device shown in FIG. 1 while the semiconductor memory device does not perform write-back.

In FIG. 3A, a write enable signal WE shifts from the high level to the low level or vice versa in accordance with a clock signal CLK. To perform the write-back for each non-selected column, data is read from each memory cell 2 in the non-selected column with the write enable signal WE being at the low level whereas the write data Di is written into each memory cell 2 in each selected column and the write-back data Dr is written back into each memory cell 2 in the non-selected column with the write enable signal WE being at the high level.

That is, if the read word line RWL becomes at the high level after the shifting of the write enable signal WE down to the low level, the read-only transfer transistor NRT in each selected row is turned on.

Accordingly, the data stored in each memory cell 2 in each non-selected column is read through the read bit line RBL of the non-selected column. If a data latch signal DLE becomes at the high level, the data read from the memory cell 2 in the non-selected column is latched by the data latch circuit 5 in the non-selected column and is outputted as the write-back data Dr to the write-back controller 6.

If the write enable signal WE shifts up to the high level, the write select signal WC becomes at the high level for each selected column, and the write select signal WC becomes at the low level for each non-selected column.

As a consequence, the write-hack controller 6 in each selected column selects write data Di, and outputs the selected write data Di to the write driver 4 in the selected column. In contrast, the write-back controller 6 in each non-selected column selects the write-back data Dr, and outputs the selected write-back data Dr to the write driver 4 in the non-selected column.

Accordingly, the write word line WWL for each selected row becomes at the high level, and thus the transfer transistors NT and NTB in the selected row are turned on. As a consequence, the write data Di is supplied to each memory cell 2 in each selected column through the write bit lines WBL and WBLB for the selected column, and is written into the memory cell 2 in the selected column. In the meanwhile, the write-back data Dr is supplied to each memory cell 2 in each non-selected column through the write bit lines WBL and WBLB for the non-selected column, and is written back into the memory cell 2 in the non-selected column.

If the write-back for each non-selected column is not performed, the read of the data from each memory cell 2 in the non-selected column is stopped with the write enable signal WE shown in FIG. 3B being at the low level. With the write enable signal WE being at the high level, the write-back data Dr is not written back into the memory cell 2 in the non-selected column, but the write data Di is written into each memory cell 2 in each selected column.

In other words, the read word line RWL is kept at the low level even after the shifting of the write enable signal WE down to the low level, and thus each read-only transfer transistor NRT in the selected row is kept in the off state.

Accordingly, the data stored in each memory cell 2 in each non-selected column is not read through the read bit line RBL for the non-selected column. Thus, the read bit line RBL for the non-selected column is kept at the high level.

In addition, with the data latch signal DLE being kept at the low level, the data read from each memory cell 2 in each non-selected column is neither latched by the data latch circuit 5 in the non-selected column, nor outputted as the write-back data Dr to the write-back controller 6.

If the write enable signal WE shifts up to the high level, the write select signal WC becomes at the high level for each selected column and the write select signal WC becomes at the low level for each non-selected column.

As a consequence, the write data Di is selected by the write-back controller 6 in each selected column, and is outputted to the write driver 4 in the selected column. Even if the write-back data Dr is selected in each non-selected column, no write-back data Dr is outputted to the write driver 4 in the non-selected column.

Hence, the write word line WWL for each selected row becomes at the high level, and thus the transfer transistors NT and NTB in the selected row are turned on. As a consequence, the write data Di is supplied to each memory cell 2 in each selected column through the write bit lines WBL and WBLB for the selected column, and is written into the memory cell 2 in the selected column. In the meanwhile, the write-back data Dr is neither supplied to each memory cell 2 in each non-selected column through the write bit lines WBL and WBLB for the non-selected column, nor written back into the memory cell 2 in the non-selected column.

Accordingly, it is possible to prevent the write-back from being performed if the operation margins of the memory cells 2 are enough to prevent disturb fault. Thus, while the prevention of write disturb is made possible by the write-back method, reduction in the power consumption can be achieved. For instance, by preventing the write-back from being performed, the charge/discharge current can be reduced in the data lines and signal lines at the hatched portions in FIG. 3A, and thus the power consumption can be reduced.

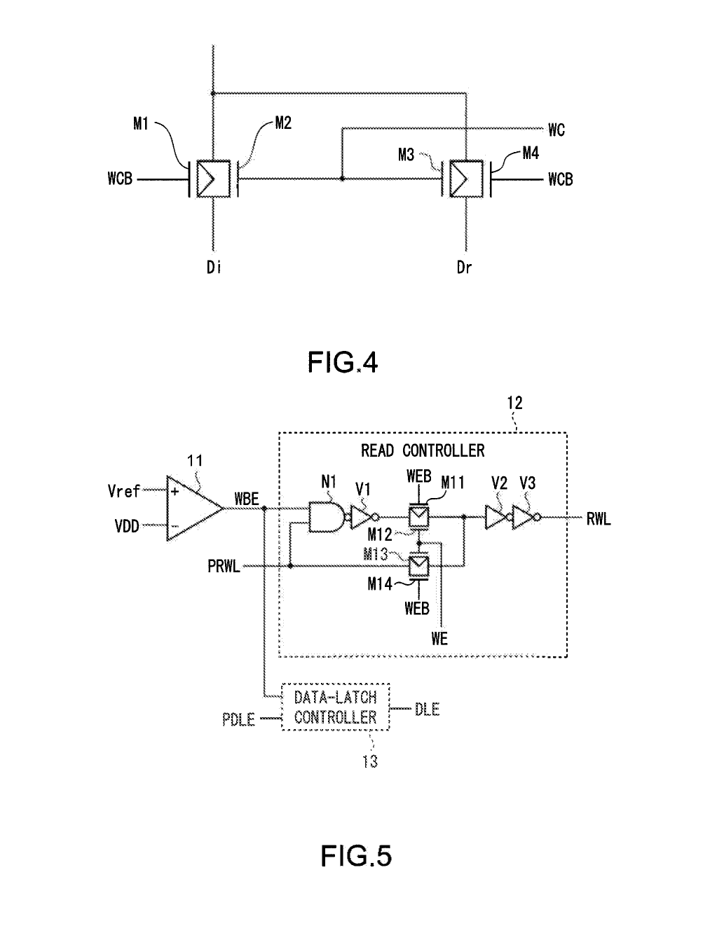

FIG. 4 is a circuit diagram illustrating the general configuration of the write-back controller shown in FIG. 1.

The write-back controller 6 shown in FIG. 4 includes P-channel field effect transistors M1 and M3 as well as N-channel field effect transistors M2 and M4. Note that reference sign WCB represents an inversion signal of the write select signal WC.

The P-channel field effect transistor M1 and the N-channel field effect transistor M2 together form a transfer gate, which is capable of allowing the write data Di to pass therethrough with the write select signal WC being at the high level, and of blocking the write data Di with the write select signal WC being at the low level.

In addition, the P-channel field effect transistor M3 and the N-channel field effect transistor M4 together form a transfer gate, which is capable of allowing the write-back data Dr to pass therethrough with the write select signal WC being at the low level, and of blocking the write-back data Dr with the write select signal WC being at the high level.

FIG. 5 is a block diagram illustrating an example of the general configuration of the write-back determining unit employed in the semiconductor memory device shown in FIG. 1.

The semiconductor memory device shown in FIG. 5 includes a comparator 11 as the write-back determining unit 7 shown in FIG. 1. In addition, the semiconductor memory device shown in FIG. 5 includes a read controller 12 as an example of the read controller 8, and a data-latch controller 13 as an example of the data-latch controller 9.

The comparator 11 is capable of comparing the power-supply voltage VDD of the memory cell 2 with the reference voltage Vref, and outputting the comparison result, as a control signal WBE, to the read controller 12 and the data-latch controller 13.

The read controller 12 includes a NAND circuit N1, inverters V1 to V3, P-channel field effect transistors M11 and M13, and N-channel field effect transistors M12 and M14. Note that reference sign WEB represents an inversion signal of the write enable signal WE.

The P-channel field effect transistor M11 and the N-channel field effect transistor M12 together form a transfer gate, which is capable of allowing an input signal to pass therethrough with the write enable signal WE being at the high level, and of blocking the input signal with the write enable signal WE being at the low level.

The P-channel field effect transistor M13 and the N-channel field effect transistor M14 together form a transfer gate, which is capable of allowing an input signal to pass therethrough with the write enable signal WE being at the low level, and of blocking the input signal with the write enable signal WE being at the high level.

One of the two input terminals of the NAND circuit N1 receives the control signal WBE whereas the other of the two input terminals of the NAND circuit N1 receives a read word line signal PRWL. The transfer gate formed by the P-channel field effect transistor M11 and the N-channel field effect transistor M12 receives the output of the NAND circuit N1 through the inverter V1. The output signal of the transfer gate is outputted to the read word line RWL through the inverter V2 and then the inverter V3.

The transfer gate formed by the P-channel field effect transistor M13 and the N-channel field effect transistor M14 receives the read word line signal PRWL. The output signal of the transfer gate is outputted to the read word line RWL through the inverter V2 and then the inverter V3. Note that the read word line signal PRWL is a signal having a similar waveform to that of the read word line RWL shown in FIG. 3A.

The data-latch controller 13 may be configured in a similar manner to the read controller 12. The data-latch controller 13 receives a data latch signal PDLE instead of the read word line signal PRWL, and outputs a data latch signal DLE instead of outputting an output signal to the read word line RWL. Note that the data latch signal PDLE is similar to the data latch signal DLE shown in FIG. 3A.

The comparator 11 compares the power-supply voltage VDD with the reference voltage Vref. If the power-supply voltage VDD is equal to or smaller than reference voltage Vref, the control signal WBE is at the high level, and the read word line signal PRWL is allowed to pass through the NAND circuit N1.

In contrast, if the power-supply voltage VDD is larger than the reference voltage Vref, the control signal WBE is at the low level, and the read word line signal PRWL is blocked by the circuit N1.

When data is read from each selected cell, the write enable signal WE becomes at the low level in the read controller 12. Hence, the transfer gate formed by the P-channel field effect transistor M11 and the N-channel field effect transistor M12 is turned off while the transfer gate formed by the P-channel field effect transistor M13 and the N-channel field effect transistor M14 is turned on.

Accordingly, the read word line signal PRWL is inputted into the read word line RWL, and thus the read word line RWL for each selected row becomes at the high level. As a consequence, the read-only transfer transistors NRT in the selected row are turned on and the data stored in each selected cell is read through the read bit line RBL.

When data is read from each selected cell, the data latch signal PDLE is inputted, as the data latch signal DLE, into the data latch circuit 5 from the data-latch controller 13, and the data latch signal DLE therein becomes at the high level. As a consequence, the data read through the read bit line RBL is latched by the data latch signal DLE, and is outputted as the read data Do.

When, on the other hand, data is written into each selected cell, the write enable signal WE becomes at the high level in the read controller 1. Hence, the transfer gate formed by the P-channel field effect transistor M1 and the N-channel field effect transistor M12 is turned on while the transfer gate formed by the P-channel field effect transistor M13 and the N-channel field effect transistor M14 is turned off.

As a consequence, the output signal of the inverter VI is inputted into the read word line RWL. Here, if the power-supply voltage VDD is equal to or smaller than the reference voltage Vref, the output signal of the inverter V1 is the read word line signal PRWL, which turns the read word line RWL for each selected row to be at the high level. As a consequence, the read-only transfer transistor NRT in the selected row is turned on, and the data stored in each memory cell 2 in each non-selected column is read through the read bit line RBL for the non-selected column.

When the power-supply voltage VDD is equal to or smaller than the reference voltage Vref in writing data into each selected cell, the data latch signal PDLE is inputted, as the data latch signal DLE, into the data latch circuit 5 from the data-latch controller 13, and the data latch signal DLE therein becomes at the high level. As a consequence, the data read through the read bit line RBL for each non-selected column is latched by the data latch signal DLE, and is outputted as the write-back data Dr.

As a consequence, the waveforms of the read word line RWL, the read bit line RBL, the data latch signal DLE, and the write-back data Dr appear as shown in FIG. 3A, and the write-back for each memory cell 2 in each non-selected column is performed.

In the read controller 12, when the power-supply voltage VDD is larger than the reference voltage Vref in writing data into each selected cell, the output signal of the inverter V1 is kept at the low level and the read word line RWL for each selected row becomes at the low level. As a consequence, the read-only transfer transistor NRT in the selected row is turned off, and the data stored in each memory cell 2 in each non-selected column is prevented from being read through the read bit line RBL for the non-selected column.

When the power-supply voltage VDD is larger than the reference voltage Vref in writing data into each selected cell, the data latch signal DLE is kept at the low level in the data-latch controller 13. As a consequence, the data read through the read bit line RBL for each non-selected column is not latched by the data latch signal DLE, and the output of the write-back data Dr is prevented.

As a consequence, the waveforms of the read word line RWL, the read bit line RBL, the data latch signal DLE, and the write-back data Dr appear as shown in FIG. 3B, and the write-back for each memory cell 2 in each non-selected column is not performed.

Accordingly, if an enough power-supply voltage VDD to secure sufficient operation margins is supplied to each memory cell 2, the write-back for each memory cell 2 in each non-selected column is prevented. Hence, while the prevention of write disturb is made possible by the write-back method, reduction in the power consumption can be achieved.

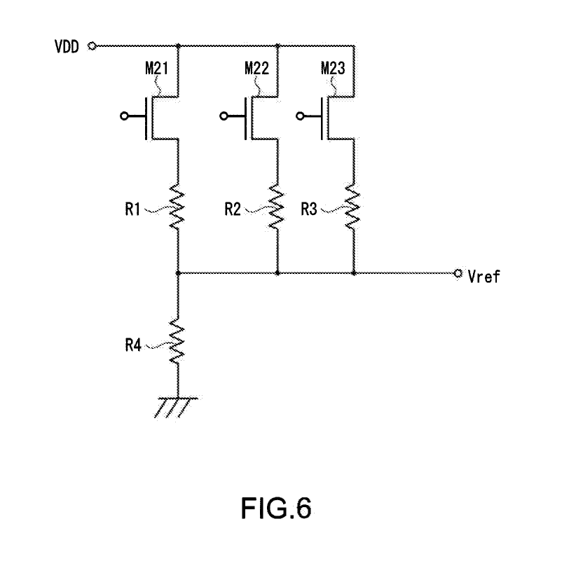

FIG. 6 is a circuit diagram illustrating an example of a trimming circuit that generates the reference voltage Vref shown in FIG. 5.

The trimming circuit shown in FIG. 6 includes N-channel field effect transistors M21 to M23 and resistors R1 to R4. The resistors R1 to R3 may have mutually different resistances.

The N-channel field effect transistor M21 is connected in series to the resistor R I The N-channel field effect transistors M22 is connected in series to the resistor R2. The N-channel field effect transistor M23 is connected in series to the resistor R3. The resistor R4 is connected commonly to the resistors R1 to R3.

With any one of the N-channel field effect transistors M21 to M23 turned on, a value that is lower than the power-supply voltage VDD by an amount equivalent to the voltage drop of the corresponding one of the resistors R1 to R3 can be used as the reference voltage Vref. Accordingly, the reference voltage Vref can be varied.

Accordingly, the reference voltage Vref can be set in accordance with the operation margins of the memory cells 2 shown in FIG. 2. Even if the memory cells 2 have different operation margins, the memory cells 2 for which write-back is not performed can be selected with higher accuracy.

### Second Embodiment

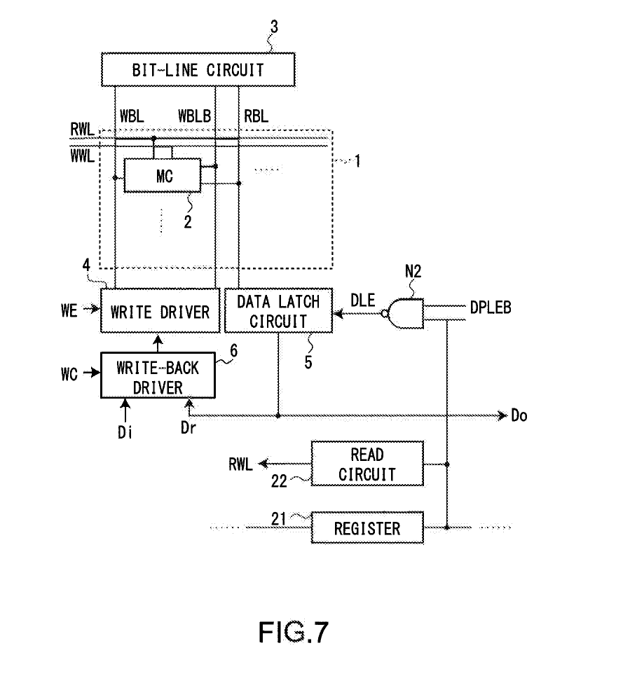

FIG. 7 is a block diagram illustrating the general configuration of a surrounding area of a memory cell of a semiconductor memory device according to a second embodiment of the invention.

The semiconductor memory device shown in FIG. 7 includes a register 21 as an example of the write-back determining unit 7 shown in FIG. 1, a read controller 22 as an example of the read controller 8, and a NAND circuit N2 as an example of the data-latch controller 9.

Here, the register 21 is capable of registering therein memory cells 2 in non-selected columns for which the write-back is to be performed. The memory cells 2 are registered on a column basis. Note that the memory cells 2 in the non-selected columns for which the write-back is to be performed may be registered in the register 21 in such a way that the memory cells 2 are grouped by plural columns. Alternatively, the registration may be done on an IO basis.

The NAND circuit N2 is capable of outputting a data latch signal DLE on the basis of the content in the register 21. One of the two input terminals of the NAND circuit N2 receives a data latch signal DPLEB whereas the other of the two input terminals of the NAND circuit N2 receives the content in the register 21. Note that the data latch signal DPLEB is an inversion signal of the data latch signal DLE shown in FIG. 3A.

The read controller 22 is capable of controlling the read of the data used in the write-back for the non-selected columns on the basis of the content in the register 21.

In the case of the non-selected columns for which the write-back is performed, the waveforms of the read word line RWL, the read bit line RBL, the data latch signal DLE, and the write-back data Dr appear as shown in FIG. 3A, and the write-back for the memory cells 2 in the non-selected columns is performed.

Conversely, in the case of the non-selected columns for which the write-back is not performed, the waveforms of the read word line RWL, the read bit line RBL, the data latch signal DLE, and the write-back data Dr appear as shown in FIG. 3B, and the write-back for the memory cells 2 in the non-selected columns is stopped.

Accordingly, if sufficient operation margins of the memory cells 2 are secured, the write-back for the memory cells 2 in the non-selected columns is prevented. Even if the memory cells 2 have different operation margins, the prevention of write disturb can be made possible by the write back method and, simultaneously, reduction in the power consumption can be achieved.

Note that if whether or not the write-back is performed is registered in the register 21 on a column basis, the registration can be done in accordance with the following procedure, for instance.

1. A die sort is performed to test the quality of each chip. In the test, the write-back is performed.

2. Defective cells picked up in the test are replaced with redundant cells to rescue the defective cells.

3. Another die sort is performed without the write-back. In the register 21, the write-back for columns including defective cells is registered as necessary, whereas the write-back for columns including no defective cells is registered as unnecessary.

1. A semiconductor memory device comprising:
a memory cell capable of writing and reading through different paths;
a write-back determining unit configured to determine whether to perform a write-back operation for a non-selected column when a write operation for a selected column is performed; and
a read controller configured to control a read operation for reading data used in the write-back for the non-selected column based on a determination result of the write-back determining unit.

2. The semiconductor memory device of claim 1, wherein
the write-back determining unit comprises a comparator configured to compare a power-supply voltage of the memory cell with a reference voltage, and
the read controller is further configured to:
allow the data to be read from the non-selected column if the power-supply voltage of the memory cell is less than or equal to the reference voltage, and
prevent the data from being read from the non-selected column if the power-supply voltage of the memory cell is larger than the reference voltage.

3. The semiconductor memory device of claim 2, further comprising a trimming circuit configured to vary the reference voltage.

4. The semiconductor memory device of claim 1, wherein
the write-back determining unit comprises a storage unit for registering on a column basis the memory cells for which the write-back is to be performed, and
the read controller further configured to allow the data to be read from the non-selected column based on the memory cells registered in the storage unit.

5. The semiconductor memory device of claim 4, wherein
the memory cell comprises:
a first drive transistor;
a second drive transistor,
a first load transistor connected in series to the first drive transistor;
a second load transistor connected in series to the second drive transistor;
a first transfer transistor whose drain is connected to a gate of the second drive transistor, a gate of the second load transistor, a drain of the first drive transistor, and a drain of the first load transistor;
a second transfer transistor whose drain is connected to a drain of the second drive transistor, a drain of the second load transistor, a gate of the first drive transistor, and a gate of the first load transistor;
a read-only drive transistor whose gate is connected to the drain of the second load transistor;
a read-only transfer transistor whose drain is connected to a drain of the read-only drive transistor;
a write word line connected to a gate of the first transfer transistor and a gate of the second transfer transistor;
a read word line connected to a gate of the read-only transfer transistor;
a first write bit line connected to a source of the first transfer transistor;
a second write bit line connected to a source of the second transfer transistor; and
a read bit line connected to a source of the read-only transfer transistor.

6. The semiconductor memory device of claim 1, further comprising a data-latch controller configured to allow the data read from the non-selected column to be latched based on the determination result of the write-back determining unit.

7. The semiconductor memory device of claim 6, wherein
the write-back determining unit comprises a comparator configured to compare a power-supply voltage of the memory cell with a reference voltage, and
the read controller is further configured to:
allow the data to be read from the non-selected column if the power-supply voltage of the memory cell is less than or equal to the reference voltage, and
prevent the data from being read from the non-selected column if the power-supply voltage of the memory cell is larger than the reference voltage.

8. The semiconductor memory device of claim 7, further comprising a trimming circuit configured to vary the reference voltage.

9. The semiconductor memory device of claim 6, wherein
the write-back determining unit comprises a storage unit for registering on a column basis the memory cells for which the write-back is to be performed, and
the read controller further configured to allow the data to be read from the non-selected column based on the memory cells registered in the storage unit.

10. The semiconductor memory device of claim 9, wherein
the memory cell comprises:
a first drive transistor;
a second drive transistor,
a first load transistor connected in series to the first drive transistor;
a second load transistor connected in series to the second drive transistor;
a first transfer transistor whose drain is connected to a gate of the second drive transistor, a gate of the second load transistor, a drain of the first drive transistor, and a drain of the first load transistor;
a second transfer transistor whose drain is connected to a drain of the second drive transistor, a drain of the second load transistor, a gate of the first drive transistor, and a gate of the first load transistor;
a read-only drive transistor whose gate is connected to the drain of the second load transistor;
a read-only transfer transistor whose drain is connected to a drain of the read-only drive transistor;
a write word line connected to a gate of the first transfer transistor and a gate of the second transfer transistor;
a read word line connected to a gate of the read-only transfer transistor;
a first write bit line connected to a source of the first transfer transistor;
a second write bit line connected to a source of the second transfer transistor; and
a read bit line connected to a source of the read-only transfer transistor.
